(19) United States
(12) Patent Application Publication
(10) Pub. No.: US 2024/0122079 A1
(43) Pub. Date: Apr. 11, 2024

(54) DIAGNOSTIC CIRCUIT

(71) Applicant: The Boeing Company, Chicago, IL (US)

(72) Inventors: Ian M. Dayton, Annapolis Junction, MD (US); Mark Edward Nowakowski, Huntington Beach, CA (US)

(21) Appl. No.: 18/045,517

(22) Filed: Oct. 11, 2022

(51) Int. Cl. H01L 39/02; G01R 33/035; H01L 39/22

(52) U.S. Cl. CPC H01L 39/025; G01R 33/0354; H01L 39/223

(57) ABSTRACT

A diagnostic circuit includes an input port configured to receive an input current and a first superconducting quantum interference device (SQUID) inductively coupled to the input port. The first SQUID is configured to generate a first output in the form of: a first voltage in response to the input current being less than a first threshold current and a second voltage in response to the input current being greater than the first threshold current. The diagnostic circuit also includes a second SQUID inductively coupled to the input port. The second SQUID is configured to generate a second output in the form of: a third voltage in response to the input current being less than a second threshold current and a fourth voltage in response to the input current being greater than the second threshold current.

### FIELD

The present disclosure generally relates to a diagnostic circuit, and more specifically to a diagnostic circuit that includes two superconducting quantum interference devices.

### BACKGROUND

In many applications, complementary metal-oxide-semiconductor (CMOS) circuits operate at cryogenic temperatures (e.g., less than or equal to 4 K corresponding to liquid helium or less than or equal to 77 K corresponding to liquid nitrogen). Methods for monitoring the performance of such CMOS circuits include sending output signals of the CMOS circuit from the location at cryogenic temperatures to a location at room temperature through long wires and/or other conditioning circuitry. The output signals are then analyzed but are typically affected by thermal noise which complicates the analysis. As such, a need exists for more accurate circuits and methods for monitoring the performance of circuits operating at cryogenic temperatures.

### SUMMARY

One aspect of the disclosure is a diagnostic circuit comprising: an input port configured to receive an input current; a first superconducting quantum interference device (SQUID) inductively coupled to the input port, wherein the first SQUID is configured to generate a first output in the form of: a first voltage in response to the input current being less than a first threshold current, and a second voltage in response to the input current being greater than the first threshold current; and a second SQUID inductively coupled to the input port, wherein the second SQUID is configured to generate a second output in the form of: a third voltage in response to the input current being less than a second threshold current, and a fourth voltage in response to the input current being greater than the second threshold current.

Another aspect of the disclosure is a method of operating a diagnostic circuit, the method comprising: receiving, via an input port of the diagnostic circuit, a first input current that is less than a first threshold current; generating, via a first superconducting quantum interference device (SQUID) of the diagnostic circuit and in response to receiving the first input current, a first output in the form of a first voltage; generating, via a second SQUID of the diagnostic circuit and in response to receiving the first input current, a second output in the form of a second voltage; receiving, via the input port, a second input current that is greater than the first threshold current and less than a second threshold current; generating, via the first SQUID and in response to receiving the second input current, the first output in the form of a third voltage; generating, via the second SQUID and in response to receiving the second input current, the second output in the form of the second voltage; receiving, via the input port, a third input current that is greater than the second threshold current; generating, via the first SQUID and in response to receiving the third input current, the first output in the form of the third voltage; and generating, via the second SQUID and in response to receiving the third input current, the second output in the form of a fourth voltage.

By the term “about” or “substantially” with reference to amounts or measurement values described herein, it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

The features, functions, and advantages that have been discussed can be achieved independently in various examples or may be combined in yet other examples further details of which can be seen with reference to the following description and drawings.

### BRIEF DESCRIPTION OF THE DRAWINGS

The novel features believed characteristic of the illustrative examples are set forth in the appended claims. The illustrative examples, however, as well as a preferred mode of use, further objectives and descriptions thereof, will best be understood by reference to the following detailed description of an illustrative example of the present disclosure when read in conjunction with the accompanying Figures.

FIG. 1 is a schematic diagram of a diagnostic circuit, according to an example.

FIG. 2 shows an output of a circuit operating at a cryogenic temperature, according to an example.

FIG. 3 shows an output of a diagnostic circuit, according to an example.

FIG. 4 is a block diagram of a method, according to an example.

FIG. 5 is a block diagram of a method, according to an example.

### DETAILED DESCRIPTION

As noted above, a need exists for more accurate circuits and methods for monitoring the performance of circuits operating at cryogenic temperatures. Accordingly, this disclosure includes a diagnostic circuit and methods for its operation. The diagnostic circuit includes an input port configured to receive an input current and a first superconducting quantum interference device (SQUID) inductively coupled to the input port. The first SQUID is configured to generate a first output in the form of: a first voltage (e.g. zero) in response to the input current being less than a first threshold current and a second voltage (e.g., 0.025 mV) in response to the input current being greater than the first threshold current. The diagnostic circuit also includes a second SQUID inductively coupled to the input port. The second SQUID is configured to generate a second output in the form of: a third voltage (e.g., zero) in response to the input current being less than a second threshold current and a fourth voltage (e.g., 0.025 mV) in response to the input current being greater than the second threshold current. The input current can be a direct output of a CMOS circuit operating at a cryogenic temperature or a representation of such an output of the CMOS circuit. Typically, the second threshold current is greater than the first threshold current such that the output transition of the first SQUID corresponds to an input current that is less than the input current that corresponds to the output transition of the second SQUID.

More generally, the diagnostic circuit can include an arbitrary number of SQUIDs that are connected in series. Each SQUID is designed to have a (e.g., unique) threshold current such that the input current exceeding the threshold current causes the SQUID to change its output from a first voltage (e.g., zero) to a second voltage (e.g., 0.025 mV). That is, the Josephson junction area for each SQUID, the material of each SQUID, and the operating temperature of the diagnostic circuit are chosen to achieve the desired threshold current for each SQUID. The input current decreasing to be less than the threshold current for a given SQUID causes the output of that SQUID to revert from the second voltage back to the first voltage. In some examples, the number of SQUIDs of the diagnostic circuit that generate a “high” voltage (e.g., 0.025 mV) instead of a “low” voltage (e.g., zero) is proportional to the voltage level being generated by the CMOS circuit. In other words, the output voltage of the series connection of the SQUIDs is proportional to the voltage level of the CMOS circuit. Thus, the diagnostic circuit acts as a sort of analog-to-digital converter that is configured to operate at cryogenic temperatures.

Due to this quantization of the output of the series connection of the SQUIDs, the output is less vulnerable to thermal noise. The diagnostic circuit can operate at the cryogenic temperature in close proximity to the CMOS circuit being monitored. Each SQUID can respond quickly to changes in the input current, for example, within 100 ps.

Disclosed examples will now be described more fully hereinafter with reference to the accompanying Drawings, in which some, but not all of the disclosed examples are shown. Indeed, several different examples may be described and should not be construed as limited to the examples set forth herein. Rather, these examples are described so that this disclosure will be thorough and complete and will fully convey the scope of the disclosure to those skilled in the art.

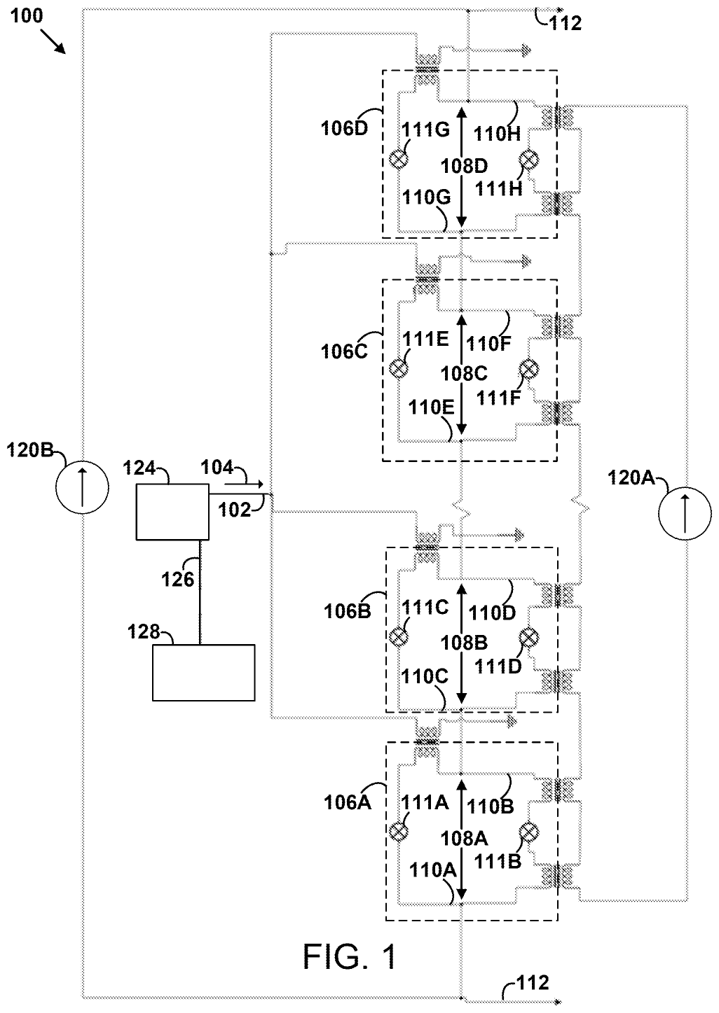

FIG. 1 is a schematic diagram of a diagnostic circuit 100 that includes an input port 102 configured to receive an input current 104. The diagnostic circuit 100 also includes a superconducting quantum interference device (SQUID) 106A inductively coupled to the input port 102 via the terminal 110B. The SQUID 106A is configured to generate an output 108A in the form of a first voltage (e.g., zero) in response to the input current 104 being less than a first threshold current and a second voltage (e.g., 0.025 mV or any voltage greater than the first voltage) in response to the input current 104 being greater than the first threshold current. The SQUID 106A is configured to generate the output 108A between the terminal 110A and the terminal 110B of the SQUID 106A.

The SQUID 106A includes a Josephson junction 111A and a Josephson junction 111B. Thus, the SQUID 106A forms a superconducting loop that includes two different superconducting materials that meet at the Josephson junction 111A and the Josephson junction 111B. The terminal 110A and the terminal 110B are inductively coupled to a current source 120A. The terminal 110A is also connected to the current source 120B. The terminal 110B is connected to the current source 120B via the SQUID 106B (e.g., via the terminal 110C), the SQUID 106C, and the SQUID 106D. The current induced within the SQUID 106A by the current source 120A and the current injected into the SQUID 106A by the current source 120B, together with the cross sectional areas of the Josephson junction 111A and the Josephson junction 111B, the choice of materials that form the Josephson junction 111A and the Josephson junction 111B, and the operating temperature of the SQUID 106A all amount to design variables or constraints that determine the threshold current that corresponds to the SQUID 106A.

The diagnostic circuit 100 also includes a superconducting quantum interference device (SQUID) 106B inductively coupled to the input port 102 via the terminal 110D. The SQUID 106B is configured to generate an output 108B in the form of a third voltage (e.g., zero) in response to the input current 104 being less than a second threshold current and a fourth voltage (e.g., 0.025 mV or any voltage greater than the third voltage) in response to the input current 104 being greater than the second threshold current. The SQUID 106B is configured to generate the output 108B between the terminal 110C and the terminal 110D of the SQUID 106B.

The SQUID 106B includes a Josephson junction 111C and a Josephson junction 111D. Thus, the SQUID 106B forms a superconducting loop that includes two different superconducting materials that meet at the Josephson junction 111C and the Josephson junction 111D. The terminal 110C and the terminal 110D are inductively coupled to the current source 120A. The terminal 110C is also connected to the current source 120B via the SQUID 106A (e.g., via the terminal 110B). The terminal 110D is connected to the current source 120B via the SQUID 106C (e.g., via the terminal 110E) and the SQUID 106D. The current induced within the SQUID 106B by the current source 120A and the current injected into the SQUID 106B by the current source 120B, together with the cross sectional areas of the Josephson junction 111C and the Josephson junction 111D, the choice of materials that form the Josephson junction 111C and the Josephson junction 111D, and the operating temperature of the SQUID 106B all amount to design variables or constraints that determine the threshold current that corresponds to the SQUID 106B.

The diagnostic circuit 100 also includes a superconducting quantum interference device (SQUID) 106C inductively coupled to the input port 102 via the terminal 110F. The SQUID 106C is configured to generate an output 108C in the form of a fifth voltage (e.g., zero) in response to the input current 104 being less than a third threshold current and a sixth voltage (e.g., 0.025 mV or any voltage greater than the fifth voltage) in response to the input current 104 being greater than the third threshold current. The SQUID 106C is configured to generate the output 108C between the terminal 110E and the terminal 110F of the SQUID 106C.

The SQUID 106C includes a Josephson junction 111E and a Josephson junction 111F. Thus, the SQUID 106C forms a superconducting loop that includes two different superconducting materials that meet at the Josephson junction 111E and the Josephson junction 111F. The terminal 110E and the terminal 110F are inductively coupled to the current source 120A. The terminal 110E is also connected to the current source 120B via the SQUID 106A and the SQUID 106B (e.g., via the terminal 110D). The terminal 110F is connected to the current source 120B via the SQUID 106D (e.g., via the terminal 110G). The current induced within the SQUID 106C by the current source 120A and the current injected into the SQUID 106C by the current source 120B, together with the cross sectional areas of the Josephson junction 111E and the Josephson junction 111F, the choice of materials that form the Josephson junction 111E and the Josephson junction 111F, and the operating temperature of the SQUID 106C all amount to design variables or constraints that determine the threshold current that corresponds to the SQUID 106C.

The diagnostic circuit 100 also includes a superconducting quantum interference device (SQUID) 106D inductively coupled to the input port 102 via the terminal 110H. The SQUID 106D is configured to generate an output 108D in the form of a seventh voltage (e.g., zero) in response to the input current 104 being less than a fourth threshold current and an eighth voltage (e.g., 0.025 mV or any voltage greater than the seventh voltage) in response to the input current 104 being greater than the fourth threshold current. The SQUID 106D is configured to generate the output 108D between the terminal 110G and the terminal 110H of the SQUID 106D.

The SQUID 106D includes a Josephson junction 111G and a Josephson junction 111H. Thus, the SQUID 106D forms a superconducting loop that includes two different superconducting materials that meet at the Josephson junction 111G and the Josephson junction 111H. The terminal 110G and the terminal 110H are inductively coupled to the current source 120A. The terminal 110H is also connected to the current source 120B. The terminal 110G is connected to the current source 120B via the SQUID 106C (e.g., via the terminal 110F), the SQUID 106B, and the SQUID 106A. The current induced within the SQUID 106D by the current source 120A and the current injected into the SQUID 106D by the current source 120B, together with the cross sectional areas of the Josephson junction 111G and the Josephson junction 111H, the choice of materials that form the Josephson junction 111G and the Josephson junction 111H, and the operating temperature of the SQUID 106D all amount to design variables or constraints that determine the threshold current that corresponds to the SQUID 106D.

Generally, the first threshold current corresponding to the SQUID 106A is less than the second threshold current corresponding to the SQUID 106B. The second threshold current corresponding to the SQUID 106B is generally less than the third threshold current corresponding to the SQUID 106C. The third threshold current corresponding to the SQUID 106C is generally less than the fourth threshold current corresponding to the SQUID 106D.

Additionally or alternatively, a difference between the first threshold current and the second threshold current can be substantially equal to a difference between the second threshold current and the third threshold current. The difference between the second threshold current and the third threshold current can be equal to the difference between the third threshold current and the fourth threshold current.

As such, the diagnostic circuit 100 is configured to generate an output voltage 112 representing a sum of the output 108A, the output 108B, the output 108C, and the output 108D. The output voltage 112 indicates a range of current that includes the present value of the input current 104.

FIG. 1 also shows a CMOS circuit 128 that is operating at a cryogenic temperature. The CMOS circuit 128 generates a CMOS output voltage 126 that is provided to conditioning circuitry 124. The conditioning circuitry 124 generates the input current 104 such that the magnitude of the input current 104 is proportional to the magnitude of the CMOS output voltage 126.

In an example, the diagnostic circuit 100 receives, via the input port 102, the input current 104 that is less than a first threshold current that corresponds to the SQUID 106A. For example, the input current 104 is equal to 0.05 mA and the first threshold current is equal to 0.1 mA. In response, the SQUID 106A generates the output 108A in the form of a voltage that is equal to zero, the SQUID 106B generates the output 108B in the form of a voltage that is equal to zero, the SQUID 106C generates the output 108C in the form of a voltage that is equal to zero, and the SQUID 106D generates the output 108D in the form of a voltage that is equal to zero. This results in the output voltage 112 of the diagnostic circuit 100 being equal to zero.

Next, the diagnostic circuit 100 receives, via the input port 102, the input current 104 that is now greater than the first threshold current 0.1 mA and less than a second threshold current 0.2 mA that corresponds to the SQUID 106B. In response, the SQUID 106A generates the output 108A in the form of a voltage that is equal to 0.025 mV, the SQUID 106B generates the output 108B in the form of a voltage that is equal to zero, the SQUID 106C generates the output 108C in the form of a voltage that is equal to zero, and the SQUID 106D generates the output 108D in the form of a voltage that is equal to zero. This results in the output voltage 112 of the diagnostic circuit 100 being equal to 0.025 mV.

Next, the diagnostic circuit 100 receives, via the input port 102, the input current 104 that is now greater than the second threshold current 0.2 mA and less than a third threshold current 0.3 mA that corresponds to the SQUID 106C. In response, the SQUID 106A generates the output 108A in the form of a voltage that is equal to 0.025 mV, the SQUID 106B generates the output 108B in the form of a voltage that is equal to 0.025 mV, the SQUID 106C generates the output 108C in the form of a voltage that is equal to zero, and the SQUID 106D generates the output 108D in the form of a voltage that is equal to zero. This results in the output voltage 112 of the diagnostic circuit 100 being equal to 0.05 mV.

Next, the diagnostic circuit 100 receives, via the input port 102, the input current 104 that is now greater than the third threshold current 0.3 mA and less than a fourth threshold current 0.4 mA that corresponds to the SQUID 106D. In response, the SQUID 106A generates the output 108A in the form of a voltage that is equal to 0.025 mV, the SQUID 106B generates the output 108B in the form of a voltage that is equal to 0.025 mV, the SQUID 106C generates the output 108C in the form of a voltage that is equal to 0.025 mV, and the SQUID 106D generates the output 108D in the form of a voltage that is equal to zero. This results in the output voltage 112 of the diagnostic circuit 100 being equal to 0.075 mV.

Next, the diagnostic circuit 100 receives, via the input port 102, the input current 104 that is now greater than the fourth threshold current 0.4 mA. In response, the SQUID 106A generates the output 108A in the form of a voltage that is equal to 0.025 mV, the SQUID 106B generates the output 108B in the form of a voltage that is equal to 0.025 mV, the SQUID 106C generates the output 108C in the form of a voltage that is equal to 0.025 mV, and the SQUID 106D generates the output 108D in the form of a voltage that is equal to 0.025 mV. This results in the output voltage 112 of the diagnostic circuit 100 being equal to 0.1 mV.

Generally, the diagnostic circuit 100 can include any arbitrary number of SQUIDS connected in series such that the output voltage 112 can be generated at any number of predefined voltage levels corresponding to different levels of the input current 104.

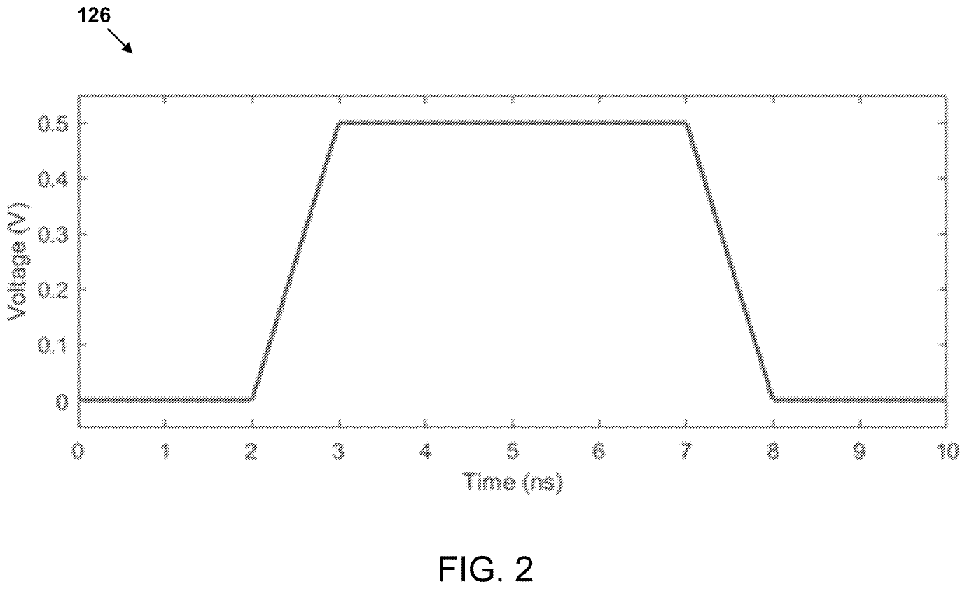

FIG. 2 shows the CMOS output voltage 126 of the CMOS circuit 128 operating at a cryogenic temperature. From 0 ns to 2 ns, the CMOS output voltage 126 is equal to 0 V. From 2 ns to 3 ns, the CMOS output voltage 126 increases linearly from 0 V to 0.5 V. From 3 ns to 7 ns, the CMOS output voltage 126 remains at 0.5 V. From 7 ns to 8 ns, the CMOS output voltage 126 decreases linearly from 0.5 V to 0 V. From 8 ns to 10 ns, the output voltage remains at 0 V.

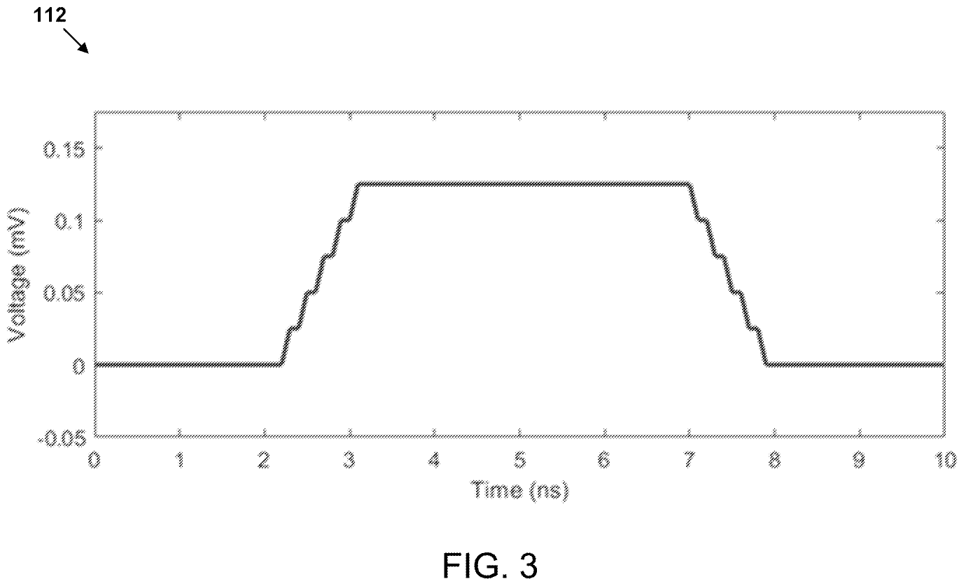

FIG. 3 shows the output voltage 112 of the diagnostic circuit 100, representing the CMOS output voltage 126 of the CMOS circuit 128 shown in FIG. 2. As shown, from 0 ns to 2 ns the output voltage 112 is equal to 0 V which corresponds to the CMOS output voltage 126 being equal to 0 V. From 2 ns to 3 ns, the output voltage 112 transitions from 0 mV to 0.025 mV, from 0.025 mV to 0.05 mV, from 0.05 mV to 0.075 mV, from 0.075 mV to 0.1 mV, and from 0.1 mV to 0.125 mV, based on the CMOS output voltage 126 transitioning from less than 0.05 V to greater than 0.05 V, from less than 0.15 V to greater than 0.15 V, from less than 0.25 V to greater than 0.25 V, from less than 0.35 V to greater than 0.35 V, and from less than 0.45 V to greater than 0.45 V, respectively. From 3 ns to 7 ns, the output voltage 112 remains at 0.125 mV based on the CMOS output voltage 126 being equal to 0.5 V (e.g., greater than 0.45 V). From 7 ns to 8 ns, the output voltage 112 transitions from 0.125 mV to 0.1 mV, from 0.1 mV to 0.075 mV, from 0.075 mV to 0.05 mV, from 0.05 mV to 0.025 mV, and from 0.025 mV to 0 mV, based on the CMOS output voltage 126 transitioning from greater than 0.45 V to less than 0.45 V, from greater than 0.35 V to less than 0.35 V, from greater than 0.25 V to less than 0.25 V, from greater than 0.15 V to less than 0.15 V, and from greater than 0.05 V to less than 0.05 V, respectively.

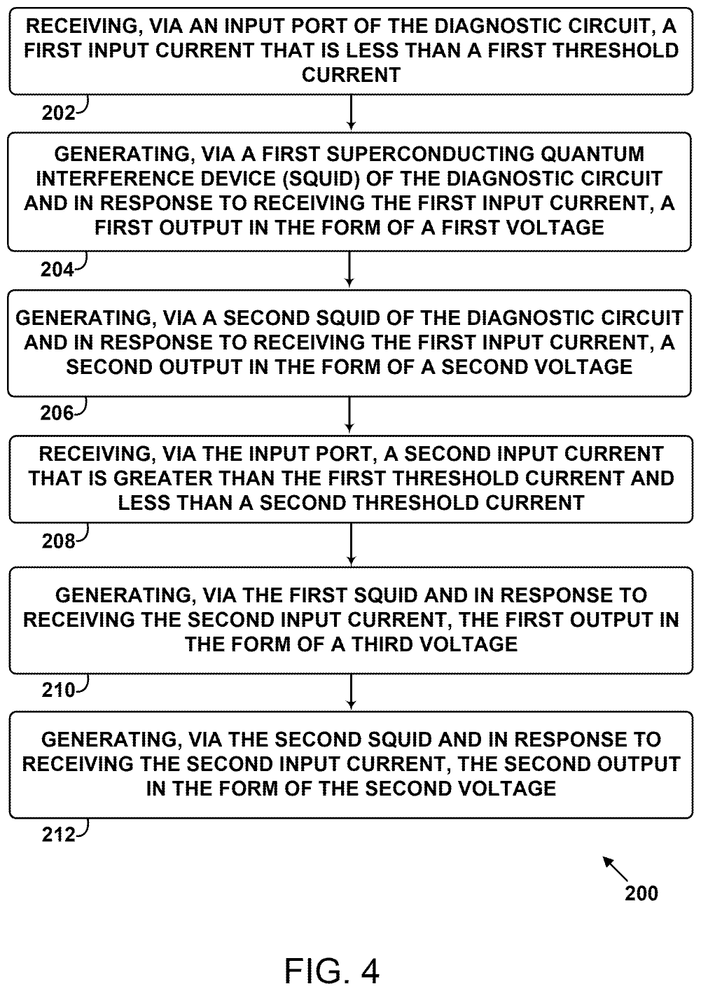

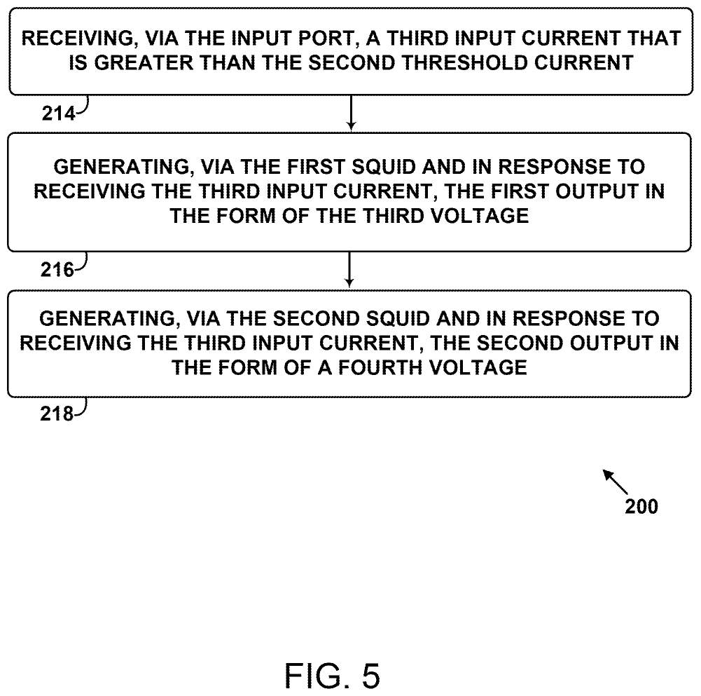

FIG. 4 and FIG. 5 are block diagrams of a method 200 for operating the diagnostic circuit 100. As shown in FIG. 4 and FIG. 5, the method 200 includes one or more operations, functions, or actions as illustrated by blocks 202, 204, 206, 208, 210, 212, 214, 216, and 218. Although the blocks are illustrated in a sequential order, these blocks may also be performed in parallel, and/or in a different order than those described herein. Also, the various blocks may be combined into fewer blocks, divided into additional blocks, and/or removed based upon the desired implementation.

At block 202, the method 200 includes receiving, via the input port 102 of the diagnostic circuit 100, the input current 104 that is less than a first threshold current. Functionality related to block 202 is described above with reference to FIGS. 1-3.

At block 204, the method 200 includes generating, via the SQUID 106A of the diagnostic circuit 100 and in response to receiving the input current 104 that is less than the first threshold current, the output 108A in the form of a first voltage. Functionality related to block 204 is described above with reference to FIGS. 1-3.

At block 206, the method 200 includes generating, via the SQUID 106B of the diagnostic circuit 100 and in response to receiving the input current 104 that is less than the first threshold current, the output 108B in the form of a second voltage. Functionality related to block 206 is described above with reference to FIGS. 1-3.

At block 208, the method 200 includes receiving, via the input port 102, the input current 104 that is greater than the first threshold current and less than a second threshold current. Functionality related to block 208 is described above with reference to FIGS. 1-3.

At block 210, the method 200 includes generating, via the SQUID 106A and in response to receiving the input current 104 that is greater than the first threshold current and less than the second threshold current, the output 108A in the form of a third voltage. Functionality related to block 210 is described above with reference to FIGS. 1-3.

At block 212, the method 200 includes generating, via the SQUID 106B and in response to receiving the input current 104 that is greater than the first threshold current and less than the second threshold current, the output 108B in the form of the second voltage. Functionality related to block 212 is described above with reference to FIGS. 1-3.

At block 214, the method 200 includes receiving, via the input port 102, the input current 104 that is greater than the second threshold current. Functionality related to block 214 is described above with reference to FIGS. 1-3.

At block 216, the method 200 includes generating, via the SQUID 106A and in response to receiving the input current 104 that is greater than the second threshold current, the output 108A in the form of the third voltage. Functionality related to block 216 is described above with reference to FIGS. 1-3.

At block 218, the method 200 includes generating, via the SQUID 106B and in response to receiving the input current 104 that is greater than the second threshold current, the output 108B in the form of a fourth voltage. Functionality related to block 218 is described above with reference to FIGS. 1-3.

The description of the different advantageous arrangements has been presented for purposes of illustration and description, and is not intended to be exhaustive or limited to the examples in the form disclosed. Many modifications and variations will be apparent to those of ordinary skill in the art. Further, different advantageous examples may describe different advantages as compared to other advantageous examples. The example or examples selected are chosen and described in order to explain the principles of the examples, the practical application, and to enable others of ordinary skill in the art to understand the disclosure for various examples with various modifications as are suited to the particular use contemplated.

What is claimed is:

1. A diagnostic circuit comprising:
an input port configured to receive an input current;
a first superconducting quantum interference device (SQUID) inductively coupled to the input port, wherein the first SQUID is configured to generate a first output in the form of:
a first voltage in response to the input current being less than a first threshold current, and
a second voltage in response to the input current being greater than the first threshold current; and
a second SQUID inductively coupled to the input port, wherein the second SQUID is configured to generate a second output in the form of:
a third voltage in response to the input current being less than a second threshold current, and
a fourth voltage in response to the input current being greater than the second threshold current.

2. The diagnostic circuit of claim 1, wherein the first SQUID comprises a first terminal and a second terminal and the first SQUID is configured to generate the first output between the first terminal and the second terminal.

3. The diagnostic circuit of claim 2, wherein the second SQUID comprises a third terminal and a fourth terminal and the second SQUID is configured to generate the second output between the third terminal and the fourth terminal.

4. The diagnostic circuit of claim 3, wherein the second terminal is connected to the third terminal.

5. The diagnostic circuit of claim 1, wherein the first voltage is substantially equal to zero.

6. The diagnostic circuit of claim 1, wherein the first voltage is less than the second voltage.

7. The diagnostic circuit of claim 1, wherein the third voltage is substantially equal to zero.

8. The diagnostic circuit of claim 1, wherein the third voltage is less than the fourth voltage.

9. The diagnostic circuit of claim 1, wherein a first difference between the first voltage and the second voltage is substantially equal to a second difference between the third voltage and the fourth voltage.

10. The diagnostic circuit of claim 1, wherein the first threshold current is less than the second threshold current.

11. The diagnostic circuit of claim 1, further comprising a third SQUID inductively coupled to the input port, wherein the third SQUID is configured to generate a third output in the form of:
a fifth voltage in response to the input current being less than a third threshold current, and
a sixth voltage in response to the input current being greater than the third threshold current,
wherein a first difference between the first threshold current and the second threshold current is substantially equal to a second difference between the second threshold current and the third threshold current.

12. The diagnostic circuit of claim 11, wherein the fifth voltage is substantially equal to zero.

13. The diagnostic circuit of claim 11, wherein the fifth voltage is less than the sixth voltage.

14. The diagnostic circuit of claim 11, wherein a third difference between the first voltage and the second voltage is substantially equal to a fourth difference between the third voltage and the fourth voltage which is substantially equal to a fifth difference between the fifth voltage and the sixth voltage.

15. The diagnostic circuit of claim 11, wherein the diagnostic circuit is configured to generate an output voltage representing a sum of the first output, the second output, and the third output.

16. The diagnostic circuit of claim 15, wherein the output voltage indicates a range of current that includes the input current.

17. A method of operating a diagnostic circuit, the method comprising:
receiving, via an input port of the diagnostic circuit, a first input current that is less than a first threshold current;
generating, via a first superconducting quantum interference device (SQUID) of the diagnostic circuit and in response to receiving the first input current, a first output in the form of a first voltage;
generating, via a second SQUID of the diagnostic circuit and in response to receiving the first input current, a second output in the form of a second voltage;
receiving, via the input port, a second input current that is greater than the first threshold current and less than a second threshold current;
generating, via the first SQUID and in response to receiving the second input current, the first output in the form of a third voltage;
generating, via the second SQUID and in response to receiving the second input current, the second output in the form of the second voltage;
receiving, via the input port, a third input current that is greater than the second threshold current;
generating, via the first SQUID and in response to receiving the third input current, the first output in the form of the third voltage; and
generating, via the second SQUID and in response to receiving the third input current, the second output in the form of a fourth voltage.

18. The method of claim 17, wherein receiving the first input current comprises receiving the first input current such that the first input current represents a state of a complementary metal-oxide semiconductor (CMOS) device operating at a cryogenic temperature.

19. The method of claim 17, wherein the first threshold current is less than the second threshold current.

20. The method of claim 17, wherein a first difference between the first voltage and the third voltage is substantially equal to a second difference between the second voltage and the fourth voltage.
